(19) United States
(12) Patent Application Publication
(10) Pub. No.: US 2025/0154660 A1
(43) Pub. Date: May 15, 2025

(54) ETCHING SOLUTION COMPOSITION, PRODUCTION METHOD FOR SAID ETCHING SOLUTION COMPOSITION, AND ETCHING METHOD USING SAID ETCHING SOLUTION COMPOSITION

(71) Applicant: KANTO KAGAKU KABUSHIKI KAISHA, Tokyo (JP)

(72) Inventors: Hiroki INAZUMI, Saitama (JP); Toshikazu SHIMIZU, Saitama (JP); Yuki YOSHIDA, Saitama (JP)

(21) Appl. No.: 18/833,162

(22) PCT Filed: Feb. 1, 2023
(86) PCT No.: PCT/JP2023/003144

§ 371 Date: Jul. 25, 2024

(30) Foreign Application Priority Data
Feb. 2, 2022 (JP) 2022-014641

(51) Int. Cl. C23F 1/26

(52) U.S. Cl. CPC C23F 1/26

(57) ABSTRACT

An object of the invention is to provide an etching solution composition which adds an excellent etched surface morphology to a metal to be etched at a suppressed etch rate. The invention relates to an etching solution composition which is obtained by blending at least (A) nitric acid, (B) acetic acid, (C) a phosphorus compound and (D) water and in which the water concentration after blending is 3.0 M or less.

### TECHNICAL FIELD

The present invention relates to an etching solution composition, a production method of the etching solution composition and an etching method using the etching solution composition.

### BACKGROUND ART

Recently, the processing speeds and the capacities of electronic devices have been significantly improved, and in particular, the memory capacities have been increased by employing a three-dimensional structure, as in a 3D NAND-type flash memory, in which memory devices are stacked vertically on a flat silicon surface. Since the capacity of a 3D NAND-type flash memory depends on the number of the layers and the like, examination for further increasing the number of the layers has still been made continuously.

In the current 3D NAND-type flash memory using tungsten for the thin gate film, however, it is concerned that the signals are delayed due to the reduction in the film thicknesses of the layers for the purpose of suppressing the increase in the size in the vertical direction caused by the increase in the number of the layers. To solve the problem, the resistance of the thin gate film material may be made lower, and examination is made to substitute the tungsten electrode with a molybdenum (Mo) electrode for the thin gate film material in the next generation devices. To produce a 3D NAND-type flash memory using a molybdenum electrode and having a high aspect structure (the number of the layers is extremely large), an etching solution which can create a desired three-dimensional structure elaborately is required.

PTL 1 discloses a production method of a touch panel sensor including a process of selectively etching a predetermined pattern on Al, an Al alloy, Ag, or an Ag alloy using a metal-layer etching solution containing water, phosphoric acid, nitric acid, and acetic acid.

PTL 2 discloses a liquid composition for etching copper or a metal compound containing copper as the main component formed on IGZO which contains (A) hydrogen peroxide, (B) a fluorine atom-free acid, (C) one kind or more of compound selected from the group consisting of a phosphonic acid, a phosphoric acid ester, 1H-tetrazole-1-acetic acid, 1H-tetrazole-5-acetic acid and 4-amino-1,2,4-triazole and (D) water.

PTL 3 discloses a liquid composition for etching copper or a metal compound containing copper as the main component formed on IGZO which contains (A) hydrogen peroxide, (B) a fluorine atom-free acid, (C) a fluorine ion source, (D) one kind or more of compound selected from the group consisting of aminotri(methylene phosphonic acid), N,N,N′,N′-ethylenediaminetetrakis(methylene phosphonic acid), diethylenetriaminepenta(methylene phosphonic acid), bis(hexamethylene)triaminepenta(methylene phosphonic acid) and pent aethylenehexamineocta(methylene phosphonic acid), (E) a hydrogen peroxide stabilizer and (F) water.

PTL 4 discloses an etching solution composition for batch etching treatment of a tungsten film and a titanium nitride film which contains nitric acid and water.

PTL 5 discloses an etching solution suitable for both a tungsten-containing metal and a TiN-containing material which contains an oxidizer, a fluorine-containing etching compound, an organic solvent, a chelating agent, a corrosion inhibitor, and a surfactant.

### CITATION LIST

### Patent Literature

PTL 1: JP2012-164079A
PTL 2: JP2016-108659A
PTL 3: JP2016-111342A
PTL 4: JP2018-006715A
PTL 5: JP2019-165225A

### SUMMARY OF INVENTION

### Technical Problem

Although various etching solution compositions have been developed as described above, an etching solution composition which can form a better pattern is required. Therefore, considering the conventional problems, an object of the invention is to provide an etching solution composition which adds an excellent etched surface morphology to a metal to be etched at a suppressed etch rate. Another object of the invention is to provide a production method of the etching solution composition and an etching method using the etching solution composition.

### Solution to Problem

While the present inventors have examined to achieve the objects, the inventors have found that an etching solution composition which is obtained by blending at least (A) nitric acid, (B) acetic acid, (C) a phosphorus compound and (D) water and in which the water concentration after blending is 3.0 M or less adds an excellent etched surface morphology to a metal to be etched at a suppressed etch rate, and as a result of further research, the invention has been completed.

That is, the invention relates to the followings.

[1] An etching solution composition obtained by blending at least (A) nitric acid, (B) acetic acid, (C) a phosphorus compound and (D) water, in which the water concentration after blending is 3.0 M or less.

[2] The etching solution composition according to [1], in which the phosphorus compound (C) is one kind or more selected from phosphoric acid, phosphonic acid, hydroxyethylidene diphosphonic acid (HEDP) and phosphorus oxide.

[3] The etching solution composition according to [1] or [2], which is obtained by further blending (E) an acid anhydride.

[4] The etching solution composition according to [3], in which the acid anhydride (E) is acetic anhydride.

[5] The etching solution composition according to any one of [1] to [4], which is obtained by blending the nitric acid (A) at a concentration of 0.5 M or more.

[6] The etching solution composition according to any one of [1] to [5], which is for etching treatment of molybdenum or a metal containing molybdenum.

[7] The etching solution composition according to any one of [1] to [6], which is for creating a pattern having a three-dimensional structure.

[8]A method for producing the etching solution composition according to any one of [1] to [7], including a process of mixing the nitric acid (A), the acetic acid (B), the phosphorus compound (C) and the water (D).

[9]A method for producing the etching solution composition according to [3] or [4], including a method of adding the acid anhydride (E) after mixing the nitric acid (A), the acetic acid (B), the phosphorus compound (C) and the water (D).

[10] An etching method using the etching solution composition according to any one of [1] to [7], in which the temperature of the etching solution composition is 15° C. to 50° C.

### Advantageous Effects of Invention

According to the invention, an etching solution composition which adds an excellent etched surface morphology to a metal to be etched at a suppressed etch rate can be provided.

In particular, in the case where the etching solution composition of the invention is used for producing a 3D NAND-type flash memory in which many thin gate films containing molybdenum and many insulating films are alternately stacked, even when the aspect ratio of the unit cell is large, the thin gate film can be etched in the entire unit cell with a nearly even recess amount (etch amount), and the morphology of the thin gate film surface after etching becomes excellent.

That is, since the composition of the invention contains water at a predetermined concentration, the composition not only adds an excellent etched surface morphology but also enables etching of the top layer and the bottom layer with nearly even recess amounts (etch amounts) also in a multi-layer laminate.

Furthermore, through addition of an acid anhydride or the like, since hydrolysis thereof with water in the composition occurs, the water concentration can be decreased, and the etch rate of molybdenum can be further suppressed.

### BRIEF DESCRIPTION OF DRAWINGS

FIG. 1 is a schematic diagram of a substrate to be etched.

FIG. 2 includes (i) a schematic diagram of an etched test substrate and (ii) an enlarged schematic diagram of pairs of thin gate films and insulating films after etching treatment.

### DESCRIPTION OF EMBODIMENTS

The invention is explained in detail below based on preferable embodiments of the invention.

The etching solution composition of the invention is obtained by blending at least (A) nitric acid, (B) acetic acid, (C) a phosphorus compound and (D) water, and the water concentration after blending is 3.0 M or less. The etching solution composition can add an excellent etched surface morphology to a metal to be etched at a suppressed etch rate.

In the present specification, that the composition “is obtained by blending” the components (A) to (D) and the like or that the components (A) to (D) and the like are “blended” means that the components (A) to (D) and the like are added as raw materials during the preparation of the etching solution composition.

Moreover, in the present specification, the “water concentration after blending” means the water concentration of the etching solution composition (at the chemical equilibrium) that is obtained after the reaction in the mixture to which all the raw materials such as the components (A) to (D) have been added has ended. For example, when the acid anhydride (E) is blended, the blending concentration of the water (D) and the water concentration after blending are not the same since the acid anhydride (E) reacts with the water (D) and is hydrolyzed.

In the present specification, the unit “M” means “mol/L”.

Furthermore, in the present specification, the numerical range “a to b” means “a or more and b or less”.

The etching solution composition of the invention is obtained by blending at least (A) nitric acid, (B) acetic acid, (C) a phosphorus compound and (D) water.

The nitric acid (A) is a component which oxidizes the metal to be etched and which contributes to the dissolution. The blended amount of the nitric acid (A) is preferably 0.5 M or more, more preferably 0.5 to 1.5 M, further preferably 0.5 to 1.0 M in view of smoothing the etched surface morphology.

The acetic acid (B) is a component which contributes to a decrease in the water concentration of the etching solution composition. The blended amount of the acetic acid (B) is preferably 10.0 to 20.0 M, more preferably 10.0 to 15.0 M, further preferably 10.0 to 12.0 M in view of smoothing the etched surface morphology.

The phosphorus compound (C) is a component which contributes to adjustment of the composition of the etching solution composition in a wider range and to smoothing of the etched surface morphology. The phosphorus compound (C) is preferably phosphoric acid, phosphonic acid, hydroxyethylidene diphosphonic acid (HEDP) or phosphorus oxide such as phosphorus pentoxide (P₂O₅). As the phosphorus compound (C), only one kind selected from the preferable compounds may be blended, or two or more kinds thereof may be blended.

The blended amount of the phosphorus compound (C) is preferably 0.5 to 2.0 M, more preferably 0.5 to 1.5 M, further preferably 0.5 to 1.0 M in view of smoothing the etched surface morphology.

The water (D) is used as a solvent in the etching solution composition. The blended amount of the water (D) is preferably 2.5 to 10.0 M, more preferably 2.5 to 5.0 M, further preferably 2.5 to 4.0 M in view of smoothing the etched surface morphology.

(E) An acid anhydride may be further blended in the etching solution composition of the invention. The acid anhydride (E) is preferably blended in the etching solution composition since the water concentration after blending can be decreased through hydrolysis reaction thereof with the blended water. The acid anhydride (E) is preferably acetic anhydride (Ac₂O), maleic anhydride or succinic anhydride, more preferably acetic anhydride or maleic anhydride, further preferably acetic anhydride. As the acid anhydride (E), only one kind selected from the preferable compounds may be blended, or two or more kinds thereof may be blended.

Acid anhydrides containing phosphorus, such as phosphorus oxide, however, belong to the phosphorus compound (C) in the present specification.

The blended amount of the acid anhydride (E) should be adjusted in such a manner that an etching solution composition having a water concentration after blending of 3.0 M or less is obtained. Specifically, the amount is preferably 1.0 to 2.9 M, more preferably 1.0 to 2.0 M, further preferably 1.0 to 1.5 M.

An optional component (also called “other optional component” below) can be blended in the etching solution composition of the invention in addition to the components described above as long as the etching treatment of the metal as the subject is not prevented. Examples of the other optional component which can be used in the invention include an organic solvent, a surfactant.

In an aspect, no peroxide is preferably blended in the etching solution composition of the invention.

Moreover, in an aspect, no ammonium salt is preferably blended in the etching solution composition of the invention.

Furthermore, in an aspect, no inorganic fluorine compound, such as hydrofluoric acid, ammonium fluoride and hexafluorosilicic acid, is preferably blended in the etching solution composition of the invention.

The etching solution composition of the invention has the water concentration after blending of etching solution composition 3.0 M or less, preferably 1.0 to 2.9 M, more preferably 1.0 to 2.0 M, further preferably 1.0 to 1.5 M.

As described above, the acid anhydride (E), which may be blended in the etching solution composition of the invention, reacts with water, and is hydrolyzed. The time required until the chemical equilibrium is reached after the hydrolysis ends varies with the kind of the blended acid anhydride (E) and the blending concentration thereof, but is generally around 5 to 15 minutes, and the water concentration after blending can be measured stably after the time has passed.

The method for measuring the water concentration after blending is not particularly limited, and for example, the water concentration after blending can be measured by the gravimetric method or the dielectric constant method.

When the water concentration after blending of the etching solution composition of the invention exceeds 3.0 M, the regulation of the etch rate becomes difficult, and inconvenience may occur, for example, when an elaborate three-dimensional structure is to be created.

Here, when the water concentration after blending of the etching solution composition of the invention is extremely high (for example, 25 M or more), there is a tendency towards re-suppression of the etch rate. When an etching solution composition having such a high-water concentration is used, however, the surface morphology of the metal to be etched may deteriorate, and an excellent etched surface morphology may not be obtained.

The metal to be etched with the etching solution composition of the invention is preferably molybdenum or a metal containing molybdenum.

It is not clear why an excellent etched surface morphology can be added to a metal to be etched at a suppressed etch rate when the etching solution composition of the invention is used, but the following mechanism may apply.

For example, when molybdenum is etched using an etching solution composition obtained by blending phosphoric acid as the phosphorus compound (C), it is considered that the reaction advances as in the following chemical equations.

Mo+2HNO₃→MoO₂+NO₂+NO+H₂O (1)

MoO₂+HNO₂→MoO₃+HNO (2)

12MoO₃+H₃PO₄+6H₂O→H₃PMo₁₂O₄₀·6H₂O (3)

As shown in the equations above, since dissolution of molybdenum requires reaction with water in the end, the equation (3) becomes the limiting factor due to the decrease in the water concentration. The etch rate is considered to be suppressed as a result.

Regarding smoothing of the etched surface morphology, it is considered as follows. Molybdenum has various oxidation states, in which compounds which easily dissolve in nitric acid, water or the like and compounds which do not easily dissolve are mixed. When molybdenum molecules in various oxidation states with different solubility in nitric acid, water or the like are mixed, the smoothness of the etched surface morphology tends to be deteriorated. On the other hand, it is considered that, when the water concentration is decreased, the complexation reaction of molybdenum can be limited to the equation (3), and as a result, the etched surface morphology can be smoothed.

The same is considered to occur also when a compound other than phosphoric acid is used as the phosphorus compound (C).

The etching solution composition of the invention is preferably used for creating a pattern having a three-dimensional structure.

The etching solution composition of the invention can add an excellent etched surface morphology particularly to molybdenum or a metal containing molybdenum at a suppressed etch rate. As a result, when a 3D NAND-type flash memory using thin gate film containing molybdenum and having a high aspect structure (the number of the layers is extremely large) is produced, a pattern having a three-dimensional structure can be created elaborately.

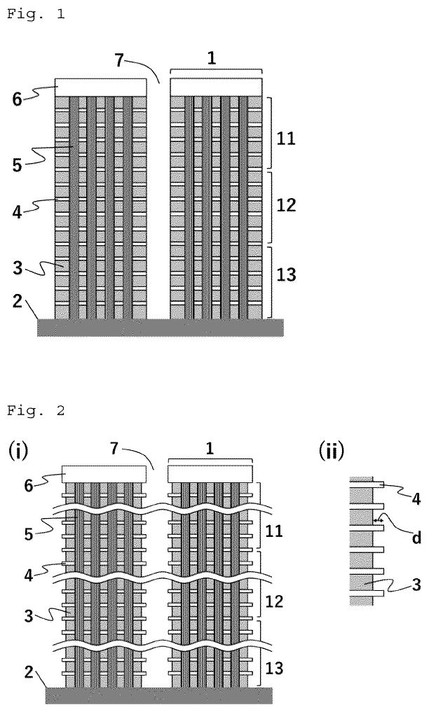

Preferable aspects of the invention are described in detail below referring to the schematic diagram of a substrate to be etched illustrated in FIG. 1.

The etching solution composition of the invention is preferably used for producing a 3D NAND flash memory from a substrate formed by alternately stacking thin gate films (wordlines) (3) and insulating films (element separation thin films between cells) (4) in the vertical direction on a Si substrate (2).

Of 3D NAND flash memories, the etching solution composition of the invention is particularly suitable for producing a 3D NAND flash memory having highly stacked layers or having a high aspect ratio of a unit cell (1). For example, when 128 flash memories are vertically stacked, at least 128 pairs of the thin gate film (3) and the insulating film (4) are formed.

When the etching solution composition of the invention is subjected to production of a 3D NAND flash memory, the subject to be etched is the thin gate films (3) of the alternately stacked films of the thin gate films (word lines) (3) and the insulating films (element separation thin films between cells) (4) in the vertical direction on the Si substrate (2).

It is needless to mention that the thin gate film (3) may contain another metal such as aluminum, magnesium, and calcium although molybdenum is the main component. Furthermore, the thin gate film (3) preferably contains molybdenum at 80 wt % or more, more preferably at 90 wt % or more, further preferably at 95 wt % or more.

The film thickness of the thin gate film (3) is preferably 100 to 7000 Å, more preferably 200 to 1000 Å, further preferably 200 to 500 Å.

Examples of insulating film (4) include SiO₂ film, Si₃N₄ film, and the film thickness of the insulating film (4) is preferably 100 to 7000 Å, more preferably 200 to 1000 Å, further preferably 200 to 500 Å.

When the etching solution composition of the invention is subjected to production of a 3D NAND flash memory, the subject particularly preferably has highly stacked layers of the thin gate films (3) and the insulating films (4). Specifically, one in which 64 pairs or more of the thin gate film (3) and the insulating film (4) are stacked is preferable, and one in which 128 pairs or more are stacked is more preferable. One in which 200 pairs or more are staked is further preferable.

A preferable subject to be etched with the etching solution composition of the invention is particularly one having a high ratio of the height (depth) and the diameter (aspect ratio) of the hole (7) in the unit cell (1) (a high aspect ratio), a height of the hole (7) of 2.5 to 10 μm, a diameter of 100 to 200 nm and height/diameter (aspect ratio) of the hole (7) of 12.5 to 100.

When a subject to be etched having such a high aspect ratio is dipped in the etching solution composition, the etching solution composition enters the opening of the hole (7) of the unit cell (1) towards the Si substrate (2) and then reaches the Si substrate (2). Therefore, the thin gate film (3) close to the opening of the hole (7) comes into contact with the etching solution composition earlier than the thin gate film (3) close to the Si substrate (2). Due to the time lag, the etch rate tends to differ with the position of the thin gate film (3) when the etch rate is determined from the dipping time and the etch amount.

On the other hand, since the etch rate of the etching solution composition of the invention is suppressed, etching advances without the difference in the etch rate described above even when the etching solution composition is used for a subject to be etched having a high aspect ratio.

For example, when the pairs of the thin gate films (3) and the insulating films (4) in the unit cell (1) are divided into three equal sections of a top layer (11), a middle layer (12) and a bottom layer (13) from the opening of the hole (7), the thin gate films (3) can be considered to be etched more evenly in the entire unit cell (1), as the ratio of the average recess amount of a plurality of points in the top layer (11) and the average recess amount of a plurality of points in the bottom layer (13) (also called “top layer/bottom layer ratio” below) is closer to 1. The top layer/bottom layer ratio is preferably 1.0 to 1.5, more preferably 1.0 to 1.2, further preferably 1.0.

The method for producing an etching solution composition of the invention includes a process of mixing (A) nitric acid, (B) acetic acid, (C) a phosphorus compound and (D) water.

Moreover, the method for producing an etching solution composition obtained by further blending (E) an acid anhydride includes a method of adding the acid anhydride (E) after mixing the nitric acid (A), the acetic acid (B), the phosphorus compound (C) and the water (D). Since the added acid anhydride (E) reacts (is hydrolyzed) with the water (D) and generates heat, the mixture is preferably left at room temperature at least for 5 to 15 minutes after the addition of the acid anhydride (E).

Preferable aspects of the components (A) to (D), the component (E) and the other optional component in the method for producing an etching solution composition of the invention are as described above.

The invention also relates to an etching method using the etching solution composition described above. The temperature (liquid temperature) of the etching solution composition during etching is 15° C. to 50° C., preferably 15° C. to 35° C., more preferably 20° C. to 30° C.

When the temperature of the etching solution composition of the invention during etching exceeds 50° C., suppression of the etch rate may not be possible. In particular, in the case of a subject to be etched having a high aspect ratio, the top layer/bottom layer ratio becomes large, and an elaborate three-dimensional structure may be difficult to create.

Preferable aspects of the components (A) to (D), the component (E) and the other optional component and preferable aspects of the metal to be etched in the etching method using an etching solution composition of the invention are as described above.

Although the invention has been explained in detail above based on preferable embodiments, the invention is not limited thereto. Each component can be replaced with any component that can exhibit a similar function, or an optional component can be added.

### EXAMPLES

The invention is shown with the Examples and the Comparative Examples below, and the contents of the invention are shown in further detail, but the invention is not limited to the Examples.

Etching solution compositions were prepared and evaluated as follows.

### [Preparation of Etching Solution Compositions]

Etching solution compositions were prepared with the blending concentrations shown in the tables below. When an acid anhydride was blended, the etching solution composition was obtained by adding the acid anhydride to a mixture containing the components excluding the acid anhydride and then leaving the mixture at room temperature for 10 minutes. The water concentrations after blending of the obtained etching solution compositions were measured by the gravimetric method. For example, when the acid anhydride (E), which caused hydrolysis reaction with the water (D), was blended, the water molar concentration before the hydrolysis reaction was calculated from the total weight of the components blended in the etching solution composition and the blending ratios, and the molar concentration of the water consumed by the hydrolysis reaction with the acid anhydride was subtracted to determine the water concentration after blending.

### [Test Substrate]

Substrates of 15×15 mm were used as test substrates. A plurality of unit cells in which thin gate films containing molybdenum and insulating films composed of SiO₂ were alternately stacked were formed on the substrates.

### [Etching of Test Substrates]

The test substrates were dipped in 100 mL of the etching solution compositions of the Examples and the Comparative Examples. The dipping was conducted for 15 minutes under stirring conditions of about 200 rpm. Here, unless otherwise clearly stated in the tables below, the liquid temperature of the etching solution composition was maintained at 25° C. while the test substrate was dipped. Subsequently, the test substrates that were taken out of the etching solution compositions were washed with deionized water and dried by blowing nitrogen gas, and thus etched test substrates were obtained.

### [Evaluation of Etch Rate and Top Layer/Bottom Layer Ratio]

The etched test substrates were cut in the middle, and the cross sections were observed using a field emission scanning electron microscope (FE-SEM: SU8220 manufactured by Hitachi High-Tech Fielding Corporation). Thus, the depths of etching in the thin gate films (the recess amounts: the lengths of etching in the parallel direction to the Si substrate) were measured. The contents of the measurement are described in detail referring to (i) the schematic diagram of an etched test substrate and (ii) the enlarged schematic diagram of pairs of thin gate films and insulating films after etching treatment illustrated in FIG. 2.

Pairs of thin gate films (3) and insulating films (4) of a unit cell (1) in each etched test substrate were divided into three equal sections of a top layer (11), a middle layer (12) and a bottom layer (13) from the opening of a hole (7), and recess amounts (d) of the thin gate films (3) were measured. Specifically, the recess amounts (d) of the thin gate films (3) were measured at 15 to 20 points each on the left and the right in each of the top layer (11), the middle layer (12) and the bottom layer (13) of one unit cell, and the averages thereof were used as the average recess amounts of the top layer (11), the middle layer (12) and the bottom layer (13).

The etch rates [nm/min.] were determined as the slopes of the lines derived from the relations between the average recess amounts of the top layer (11), the middle layer (12) and the bottom layer (13) and the dipping time of the test substrate.

Moreover, the top layer/bottom layer ratio was calculated by dividing the average recess amount of the top layer (11) by the average recess amount of the bottom layer (13).

### [Evaluation of Etched Surface Morphology]

The thin gate film surfaces of the test substrates after the etching treatment which were cut as described above were observed with image analysis software (ImageJ), and the morphology thereof was evaluated as follows.
∘ (Good): A smooth thin gate film surface was observed.
x (Poor): A rough thin gate film surface was observed.

### Examples 1 to 7

The etching solution compositions of Examples 1 to 7 were prepared with the blending concentrations shown in the table below, and the test substrates were etched.

TABLE 1

| | | | | | | Water | | | | | |
|---|---|---|---|---|---|---|---|---|---|---|---|
| | | | | | | Concentration | Etch Rate [nm/min.] | | | Top | Etched |
| | Blending Concentration [M] | | | | | [M] After | Top | Middle | Bottom | Layer/Bottom | Surface |
| | H₂O | H₃PO₄ | HNO₃ | AcOH | AC₂O | Blending | Layer | Layer | Layer | Layer Ratio | Morphology |
| Example 1 | 3.7 | 0.7 | 0.5 | 11.1 | 2.7 | 1 | 1.5 | 1.5 | 1.5 | 1 | ◯ |
| Example 2 | 3.7 | 0.7 | 1.1 | 10.8 | 2.7 | 1 | 1.7 | 1.8 | 1.8 | 1 | ◯ |
| Example 3 | 3.7 | 0.7 | 1.1 | 10.9 | 2.5 | 1.2 | 4.2 | 4.6 | 4.5 | 0.9 | ◯ |
| Example 4 | 3.8 | 0.7 | 1.1 | 11.3 | 2.4 | 1.4 | 5.8 | 5.8 | 5.5 | 1.1 | ◯ |
| Example 5 | 3.9 | 0.7 | 1.1 | 10.8 | 2.4 | 1.5 | 7 | 6.6 | 6.1 | 1.1 | ◯ |
| Example 6 | 4.4 | 0.7 | 1.1 | 11.3 | 2.3 | 2.1 | 17.2 | 12 | 11.2 | 1.5 | ◯ |
| Example 7 | 4.7 | 0.7 | 1.1 | 10.8 | 2.6 | 2.1 | 12 | 11.1 | 10.3 | 1.2 | ◯ |

With the etching solution compositions of Examples 1 to 7, in which phosphoric acid was blended as the phosphorus compound (C), the top layer, the middle layer and the bottom layer of the test substrate using thin gate films containing molybdenum could be etched with nearly even recess amounts. Moreover, the morphology of the thin gate film surface (the etched surface morphology) after the etching treatment was excellent.

It was further found that by adjusting the blending concentration of acetic anhydride (Ac₂O) as the acid anhydride (E), the water concentration after blending is adjusted, and the etch rate can be adjusted.

### Examples 8 to 11

The etching solution compositions of Examples 8 to 11 were prepared with the blending concentrations shown in the table below, and the test substrates were etched.

TABLE 2

| | | | | | Water | | | | | |
|---|---|---|---|---|---|---|---|---|---|---|
| | | | | | Concentration | Etch Rate [nm/min.] | | | Top | Etched |
| | Blending Concentration [M] | | | | [M] After | Top | Middle | Bottom | Layer/Bottom | Surface |
| | H₂O | HNO₃ | AcOH | P₂O₅ | Blending | Layer | Layer | Layer | Layer Ratio | Morphology |
| Example 8 | 2.5 | 1.1 | 16.3 | 0.8 | 0.2 | 0.4 | 0.4 | 0.4 | 1.1 | ◯ |
| Example 9 | 2.5 | 1.1 | 16.3 | 0.6 | 0.7 | 0.6 | 0.6 | 0.6 | 1.1 | ◯ |
| Example 10 | 2.5 | 1.1 | 16.3 | 0.5 | 1 | 0.8 | 0.8 | 0.8 | 1.1 | ◯ |
| Example 11 | 2.5 | 1.1 | 16.3 | 0.4 | 1.4 | 3.8 | 3.7 | 3.5 | 1.1 | ◯ |

With the etching solution compositions of Examples 8 to 11, in which phosphorus pentoxide (P₂O₅) was blended as the phosphorus compound (C), the top layer, the middle layer and the bottom layer of the test substrate using thin gate films containing molybdenum could be etched with nearly even recess amounts. Moreover, the morphology of the thin gate film surface (the etched surface morphology) after the etching treatment was excellent.

It was further found that by adjusting the blending concentration of phosphorus pentoxide, the water concentration after blending is adjusted, and the etch rate can be adjusted.

### Examples 12 to 14

The etching solution composition of Example 2 was prepared, and the test substrates were etched at different liquid temperatures shown in the table below.

TABLE 3

| | | | | | | Liquid Temper- | | | | | |
|---|---|---|---|---|---|---|---|---|---|---|---|
| | | | | | | ature [° C.] | | | | | |
| | | | | | | of Etching | Etch Rate [nm/min.] | | | Top | Etched |
| | Blending Concentration [M] | | | | | solution | Top | Middle | Bottom | Layer/Bottom | Surface |
| | H₂O | H₃PO₄ | HNO₃ | AcOH | Ac₂O | composition | Layer | Layer | Layer | Layer Ratio | Morphology |
| Example 2 | 3.7 | 0.7 | 1.1 | 10.8 | 2.7 | 25 | 1.7 | 1.8 | 1.8 | 1 | ◯ |
| Example 12 | 3.7 | 0.7 | 1.1 | 10.8 | 2.7 | 30 | 4.6 | 5 | 4.7 | 1 | ◯ |
| Example 13 | 3.7 | 0.7 | 1.1 | 10.8 | 2.7 | 40 | 12.9 | 11.3 | 10.2 | 1.3 | ◯ |
| Example 14 | 3.7 | 0.7 | 1.1 | 10.8 | 2.7 | 50 | 30.3 | 23.7 | 22.1 | 1.4 | ◯ |

With the etching solution composition of Example 2, the top layer, the middle layer, and the bottom layer of the test substrate using thin gate films containing molybdenum could be etched with nearly even recess amounts in the liquid temperature range of 25 to 50° C. (Examples 12 to 14). Moreover, the morphology of the thin gate film surface (the etched surface morphology) after the etching treatment at the respective liquid temperatures was excellent.

It was further found that by adjusting the liquid temperature of the etching solution composition, the etch rate can be adjusted.

### Examples 15 to 19

The etching solution compositions of Examples 15 to 19 were prepared with the blending concentrations shown in the table below, and the test substrates were etched.

TABLE 4

| | | | | | Etch Rate [nm/min.] | | | Top | Etched |
|---|---|---|---|---|---|---|---|---|---|
| | Blending Concentration [M] | | | | Top | Middle | Bottom | Layer/Bottom | Surface |
| | H₂O | HEDP | HNO₃ | AcOH | Layer | Layer | Layer | Layer Ratio | Morphology |
| Example 15 | 1.95 | 0.10 | 0.50 | 16.41 | 0.7 | 0.8 | 0.9 | 0.8 | ◯ |
| Example 16 | 2.01 | 0.11 | 0.50 | 16.37 | 0.8 | 0.8 | 0.8 | 1.1 | ◯ |
| Example 17 | 2.17 | 0.10 | 0.60 | 16.29 | 0.8 | 1.0 | 0.9 | 0.8 | ◯ |
| Example 18 | 2.40 | 0.10 | 0.70 | 16.17 | 0.9 | 1.2 | 1.1 | 0.8 | ◯ |
| Example 19 | 2.61 | 0.10 | 0.80 | 16.05 | 1.3 | 1.6 | 1.6 | 0.9 | ◯ |

With the etching solution compositions of Examples 15 to 19, in which hydroxyethylidene diphosphonic acid (HEDP) was blended as the phosphorus compound (C), the top layer, the middle layer and the bottom layer of the test substrate using thin gate films containing molybdenum could be etched with nearly even recess amounts. Moreover, the morphology of the thin gate film surface (the etched surface morphology) after the etching treatment was excellent.

### Comparative Examples 1 to 4

The etching solution compositions of Comparative Examples 1 to 4 were prepared with the blending concentrations shown in the table below, and the test substrates were etched.

TABLE 5

| | | | | | Water | | | | | |
|---|---|---|---|---|---|---|---|---|---|---|
| | | | | | Concentration | Etch Rate [nm/min.] | | | Top | Etched |
| | Blending Concentration [M] | | | | [M] After | Top | Middle | Bottom | Layer/Bottom | Surface |
| | H₂O | H₃PO₄ | HNO₃ | AcOH | Blending | Layer | Layer | Layer | Layer Ratio | Morphology |
| Comparative | 45.46 | 4.53 | 0.1 | — | 45.5 | — | — | — | — | X |
| Example 1 | | | | | | | | | | |
| Comparative | 14.11 | 11.4 | 0.47 | 2.66 | 14.1 | >100 | >100 | >100 | — | ◯ |
| Example 2 | | | | | | | | | | |
| Comparative | 8.71 | 7.12 | 0.11 | 8.98 | 8.7 | 14 | 6.8 | 4.3 | 3.2 | ◯ |
| Example 3 | | | | | | | | | | |
| Comparative | 3.05 | 0.7 | 1.05 | 15.56 | 3.1 | 39.7 | 23.3 | 18.5 | 2.1 | ◯ |
| Example 4 | | | | | | | | | | |

The etching solution composition of Comparative Example 1, which had an extremely high water concentration after blending of 45.5 M, deteriorated the morphology of the thin gate film surface (the etched surface morphology) after the etching treatment. It was thus found that recesses cannot be formed normally when the etch rate is decreased by increasing the water concentration.

Moreover, it was found that, with the etching solution compositions of Comparative Examples 2 to 4, in which the water concentration after blending was decreased insufficiently, the etch rate of the test substrate using thin gate films containing molybdenum could not be suppressed sufficiently, or etching with an even recess amount was not possible due to the large top layer/bottom layer ratio. This indicates that a decrease in the water concentration after blending is important to obtain aimed etching performance.

### Comparative Examples 5 to 101

The etching solution compositions of Comparative Examples 5 to 10 were prepared with the blending concentrations shown in the table below, and the test substrates were etched.

TABLE 6

| | | | | | | Water | | | | | |
|---|---|---|---|---|---|---|---|---|---|---|---|
| | | | | | | Concentration | Etch Rate [nm/min.] | | | Top | Etched |
| | Blending Concentration [M] | | | | | [M] After | Top | Middle | Bottom | Layer/Bottom | Surface |
| | H₂O | H₃PO₄ | HNO₃ | AcOH | Ac₂O | Blending | Layer | Layer | Layer | Layer Ratio | Morphology |
| Comparative | 5.3 | 0.7 | 1.1 | 11.3 | 2.2 | 3.1 | 31.3 | 19.5 | 14.4 | 2.2 | ◯ |
| Example 5 | | | | | | | | | | | |
| Comparative | 7.2 | 0.7 | 1.1 | 11.3 | 1.8 | 5.4 | 79 | 28.9 | 14.7 | 5.4 | ◯ |
| Example 6 | | | | | | | | | | | |
| Comparative | 5.7 | 0.7 | 1.1 | 10.8 | 2.4 | 3.3 | 36.1 | 26 | 20.6 | 1.7 | ◯ |
| Example 7 | | | | | | | | | | | |
| Comparative | 7.5 | 0.7 | 1.1 | 10.8 | 2 | 5.5 | 73.2 | 38.5 | 32.3 | 2.3 | ◯ |
| Example 8 | | | | | | | | | | | |

TABLE 7

| | | | | | Water | | | | | |
|---|---|---|---|---|---|---|---|---|---|---|
| | | | | | Concentration | Etch Rate [nm/min.] | | | Top | Etched |
| | Blending Concentration [M] | | | | [M] After | Top | Middle | Bottom | Layer/Bottom | Surface |
| | H₂O | HNO₃ | AcOH | P₂O₅ | Blending | Layer | Layer | Layer | Layer Ratio | Morphology |
| Comparative | 6.2 | 1.1 | 15.1 | 0.4 | 5 | 118.1 | 30.2 | 9.3 | 12.7 | ◯ |
| Example 9 | | | | | | | | | | |
| Comparative | 18.6 | 1 | 11.3 | 0.3 | 17.7 | 156.7 | 20.3 | 6.7 | 23.2 | ◯ |
| Example 10 | | | | | | | | | | |

It was found that, with the etching solution compositions of Comparative Examples 5 to 10, in which the water concentration after blending was decreased insufficiently, the suppression of the etch rate of the test substrate using thin gate films containing molybdenum was difficult, and etching with an even recess amount was not possible due to the large top layer/bottom layer ratio. This indicates that a decrease in the water concentration after blending is important to obtain aimed etching performance.

### Comparative Example 11

Using the etching solution composition of Example 2, the test substrate was etched at the liquid temperature shown in the table below.

TABLE 8

| | | | | | | | Etch Rate [nm/min.] | | | Top | Etched |
|---|---|---|---|---|---|---|---|---|---|---|---|
| | Blending Concentration [M] | | | | | Temperature | Top | Middle | Bottom | Layer/Bottom | Surface |
| | H₂O | H₃PO₄ | HNO₃ | AcOH | Ac₂O | [° C.] | Layer | Layer | Layer | Layer Ratio | Morphology |
| Example 2 | 3.7 | 0.7 | 1.1 | 10.8 | 2.7 | 25 | 1.7 | 1.8 | 1.8 | 1 | ◯ |
| Comparative | 3.7 | 0.7 | 1.1 | 10.8 | 2.7 | 60 | 70.8 | 49.1 | 42 | 17 | ◯ |
| Example 11 | | | | | | | | | | | |

It was found that, when the test substrate using thin gate films containing molybdenum was etched with the etching solution composition of Example 2 at the liquid temperature of 60° C., the etch rate of molybdenum increased significantly, and thus etching with an even recess amount was not possible due to the large top layer/bottom layer ratio (Comparative Example 11). This indicates that the temperature (liquid temperature) of the etching solution composition during etching is important to appropriately exhibit aimed etching performance.

### INDUSTRIAL APPLICABILITY

Using the etching solution composition of the invention, an excellent etched surface morphology can be added to a metal to be etched at a suppressed etch rate. In particular, the etching solution composition of the invention can be preferably used for producing a 3D NAND-type flash memory in which many thin gate films containing molybdenum and many insulating films are alternately stacked.

### REFERENCE SIGNS LIST

1: Unit cell
2: Si substrate
3: Thin gate film
4: Insulating film
5: Poly-Si channel
6: Insulating film
7: Hole
11: Top layer
12: Middle layer
13: Bottom layer
d: Recess amount

1. An etching solution composition obtained by blending at least (A) nitric acid, (B) acetic acid, (C) a phosphorus compound, and (D) water, wherein the water concentration after blending is 3.0 M or less.

2. The etching solution composition of claim 1, wherein the phosphorus compound (C) is one or more selected from phosphoric acid, phosphonic acid, hydroxyethylidene diphosphonic acid (HEDP), and phosphorus oxide.

3. The etching solution composition of claim 1, which is obtained by further blending (E) an acid anhydride.

4. The etching solution composition of claim 3, wherein the acid anhydride (E) is acetic anhydride.

5. The etching solution composition of claim 1, which is obtained by blending the nitric acid (A) at a concentration of 0.5 M or more.

6. The etching solution composition of claim 1, which is for etching treatment of molybdenum or a metal containing molybdenum.

7. The etching solution composition of claim 1, which is for creating a pattern having a three-dimensional structure.

8. A method for producing the etching solution composition of claim 1, comprising a process of mixing the nitric acid (A), the acetic acid (B), the phosphorus compound (C), and the water (D).

9. A method for producing the etching solution composition of claim 1, comprising a method of adding the acid anhydride (E) after mixing the nitric acid (A), the acetic acid (B), the phosphorus compound (C), and the water (D).

10. An etching method using the etching solution composition of claim 1, wherein the temperature of the etching solution composition is 15° C. to 50° C.
